(19) United States
(12) Patent Application Publication
(10) Pub. No.: US 2015/0144186 A1
(43) Pub. Date: May 28, 2015

(54) Methods and Materials for the Improvement of Photovoltaic Device Performance

(71) Applicant: Alliance for Sustainable Energy, LLC, Golden, CO (US)

(72) Inventor: Timothy A. Gessert, Conifer, CO (US)

(21) Appl. No.: 14/401,485

(22) PCT Filed: May 16, 2013
(86) PCT No.: PCT/US2013/041431

§ 371 Date: Nov. 14, 2014

Related U.S. Application Data
(60) Provisional application No. 61/647,928, filed on May 16, 2012.

(51) Int. Cl. H01L 31/0749; C22C 28/00; H01L 31/18; H01L 31/0224

(52) U.S. Cl. CPC H01L 31/0749; H01L 31/022466; C22C 28/00; H01L 31/1828
USPC 136/256; 420/579; 438/95

(57) ABSTRACT

Embodiments disclosed herein include photovoltaic absorber materials (302) and photovoltaic devices (300) having absorber materials (302) with intentionally increased permittivity. Alternative embodiments include methods (200) of producing thin film photovoltaic absorbers (302) from materials having increased permittivity or methods of producing devices having absorbers (302) with increased permittivity. In selected embodiments, the permittivity of an absorber material (302) is increased by incorporating a permittivity increasing material therein.

### PRIORITY

This application claims the benefit under 35 USC section 119 of U.S. provisional application 61/647,928 filed on May 16, 2012 and entitled “Improvement of CdTe Photovoltaic Device Performance By CdTe material Enhancements” the content of which is hereby incorporated by reference in its entirety and for all purposes.

### CONTRACTUAL ORIGIN

The United States Government has rights in this invention under Contract No. DE-AC36-08GO28308 between the United States Department of Energy and the Alliance for Sustainable Energy, LLC, the manager and operator of the National Renewable Energy Laboratory.

### BACKGROUND

Thin-film photovoltaic (PV) devices based on CdS/CdTe and other thin film technologies represent one of the fastest-growing segments of the PV industry. In a typical CdS/CdTe design, light enters the device through a transparent glass “superstrate,” is transmitted through one or more transparent conducting oxide (TCO) layers, one or more buffer layers and through an n-type CdS window layer. The light is then absorbed in a CdTe absorber.

Often, an “as-deposited” CdTe absorber is of insufficient electrical quality for effective junction operation. Many factors affect the suitability of a CdTe layer for photovoltaic operation, including the CdTe source material, the specifics of the CdTe deposition steps and selected treatment processes. One problem often faced in PV device design and fabrication is that the net acceptor density of the CdTe layer will be too low for optimal device operation. In other instances, the CdTe material may be n-type prohibiting device operation. Even if the acceptor density is sufficiently high in the CdTe (and other thin film absorber materials) the innate, as-deposited, minority-carrier lifetime (τ) is generally too short for optimum absorber operation in these materials.

The foregoing problems have typically been addressed by a combination of CdCl₂ activation and back contacting processes that diffuse one or more dopant species into the CdTe layer. Although Cu has been historically favored as the active diffusing dopant species, other group 11/IB species (for example Au or Ag) or group 15/VB species (for example N, P, As, Sb, or Bi) have been found to demonstrate some potential for this use. Although the precise mechanism that occurs during dopant diffusion remains debated, it is known that a successful diffusion alters the electrical properties of the underlying CdTe layer so that it becomes sufficiently p-type to establish a strong field in the device regions near the n-type CdS layer. Furthermore, controlled Cu diffusion at an appropriate temperature has been found to increase τ within the CdTe layer.

Although it is known that Cu diffusion from the back contact of a CdS/CdTe thin-film solar cell can enhance device performance, it is also well known that Cu diffusion can be linked to device instability. Research concerning ZnTe:Cu/Ti back contacts have enabled aspects of Cu diffusion to be studied under conditions that afford a degree of process control. Thus, it is known that as Cu from a Cu-containing contact layer enters the CdTe layers of a device the acceptor concentration in the CdTe layer (N_{A}) increases significantly. This causes important changes in the electrical properties of the CdTe layer, and these changes have been strongly linked to performance improvements of the PV device.

Initially, it may be noted that increasing N_{A} increases the built-in voltage (V_{bi}) of the junction, thereby increasing the open-circuit voltage (V_{oc} of the device. The increase in V_{bi} as a function of N_{A} is described by Equation 1, where N_{A} is the p-type acceptor density in CdTe, and N_{D} is the donor density in the n-type region of the junction (often the CdS-alloy layer).

$${V}_{oc} ∝ {V}_{b i} = \frac{kT}{q} ln \frac{ {N}_{A} {N}_{D}}{{n}_{i}^{2}} \qquad Equation 1$$

In Equation 1, k is the Boltzmann constant, and nᵢ is the intrinsic carrier density. nᵢ is therefore a temperature- and material-dependent parameter that represents the carrier density in the conduction and/or valance band when an material does not contain impurities or lattice defects.

In addition to increasing V_{b}, as N_{A} increases, the extent of the region containing the junction electric field, known as the space charge width (W_{D}) decreases. The reduction in W_{D} with increased N_{A} is described in Equation 2, where ∈ₛ is the dielectric permittivity:

$${W}_{D} = \sqrt{\frac{2 {ɛ}_{s} {V}_{bi}}{{qN}_{A}}} \qquad Equation 2$$

Equation 2 assumes that the reduction in W_{D} is caused primarily by N_{A} increasing in the CdTe layer, and is known as the one-sided junction approximation. However, W_{D} can also be impacted by increase or decrease in N_{D} in the n-type CdS-alloy layer.

A third effect of Cu diffusion is that the minority-carrier lifetime (τ) in the CdTe layer increases when Cu diffusion conditions are optimized but decreases under less than optimum conditions. τ optimization can be controlled by contact processing parameters, such as the amount of Cu in the contact layers(s), the diffusion temperature, the diffusion time, and the condition of the CdTe layer prior to diffusion. Increasing τ can improve device performance because more of the light-generated carriers can be collected for the purpose of doing useful work. When τ is too short, carriers recombine before collection and mostly yield non-beneficial heat in a photovoltaic device. The highest performing devices are produced presently when a carefully controlled amount of Cu is diffused into the CdTe at a temperature of about 280° C. to 320° C. This produces an indicated W_{D} of approximately 0.5 μm when measured using capacitive voltage analysis at 0.6 V forward bias, and a τ of approximately 2 ns when measured with single-photon, time-resolved photoluminescence.

An optimized device using a ZnTe:Cu/Ti back contact is schematically illustrated in FIG. 1A. The device 100 of FIG. 1 receives solar radiation 102 at a front-side glass superstate 104. The light passes through one or more transparent conducting oxide and/or buffer layers 106, an n-doped CdS-alloy window layer 108 and is absorbed primarily in a p-doped absorber 110. Incident photons are absorbed throughout a portion of the depth of the absorber, based upon the wavelength of the incident photon and the bandgap of the absorber material. The absorption depth is schematically represented by the arrow 112 of FIG. 1A. The device is completed with one or more back contact interface layers 114 and a back metal contact 116.

As schematically illustrated in FIG. 1A, and noted above, a portion of the depth of the absorber 110 near the p-n junction comprises the space charge width W_{D} 118. Photons absorbed within the region of W_{D} 118 are most readily converted to electrical energy. The balance of the absorber 110 forms a quasi-neutral region 120.

A problem arises in a junction prepared to have relatively higher N_{A} because both V_{bi} and W_{D} depend on the value of N_{A} in the CdTe or other absorber. Therefore, increased N_{A} can both benefit and hinder device performance. N_{A} should be as high as possible to increase V_{oc} yet, as N_{A} increases, W_{D} can become so narrow that fewer light-generated charges are generated within W_{D}. W_{D} becomes too small, some light is absorbed in a region of the CdTe layers that does not have a strong electric field, specifically in the quasi-neutral region 120 of the CdTe absorber 110 and the resulting light-generated carriers are more likely to recombine before collection.

This undesirable condition is schematically illustrated in FIG. 1B with reference numerals 100-120 identifying the same structures or regions as noted above with respect to FIG. 1A. In the FIG. 1B device however, W_{D} 118 has become too small as the result of an increase of N_{A}. Accordingly, the absorption depth 112 is positioned within the absorber such that a significant number of photons are absorbed in the quasi-neutral region of the absorber 120 and the light-generated carriers formed in this region are generally not collected before recombination.

In certain “high-τ” materials (e.g., GaAs, Si, CuInGaSe₂, etc.) having W_{D} smaller than the distance of light absorption in the junction region is not as detrimental. In these other materials, charges generated in the quasi-neutral region can still be collected because the minority carrier lifetimes are longer, with τ in the range of 10-200 ns being observed for some materials. Unfortunately, as noted above, many materials suitable for use as PV absorbers, including but not limited to polycrystalline CdTe, CIGS, Cu₂ZnSn(S, Se)₄ (CZTS) and others have a relatively short minority carrier lifetimes, causing minority carriers generated outside of W_{D} to be uncollected. This leads to voltage-dependent collection that manifests as a loss in fill factor as the device voltage approaches V_{oc}. Accordingly, for the present generation of CdS/CdTe, CIGS, CZTS and other “low τ” photovoltaic devices, lower performance typically results as the N_{A} is increased beyond a certain value.

Various approaches are being pursued in an attempt to increase both V_{oc} and device fill factor. The embodiments disclosed herein comprise a new approach to addressing the problems set forth above. The foregoing examples of the related art and limitations related therewith are intended to be illustrative and not exclusive. Other limitations of the related art will become apparent to those of skill in the art upon a reading of the specification and a study of the drawings.

### SUMMARY

Embodiments disclosed herein include photovoltaic absorber materials and photovoltaic devices including absorber materials with intentionally increased permittivity. Alternative embodiments include methods of producing thin film photovoltaic absorbers from materials having increased permittivity or methods of producing devices having absorbers with increased permittivity.

One embodiment is a method of producing a thin film photovoltaic absorber having intentionally increased permittivity by incorporating a permittivity increasing material into the absorber material. The permittivity increasing material may be incorporated into the absorber material according to any desired compositional ratio. For example, in certain embodiments, the permittivity increasing material may comprise 0.01% to 10% of the thin film photovoltaic absorber after incorporation. Alternatively, the permittivity increasing material may comprise 0.1% to 5% of the thin film photovoltaic absorber after incorporation.

Certain embodiments disclosed herein can be methods useful for the manufacture of high efficiency photovoltaic (PV) devices, including but not limited to methods of manufacturing CdS/CdTe PV devices having a CdTe absorber. The embodiments disclosed herein are not so limited and include similar methods, devices and absorber materials in the fields of CIGS, Cu₂ZnSn(S, Se)₄ (CZTS) compounds and other PV technologies that utilize absorbers which can be improved by increasing the permittivity of the absorber material. With respect to certain embodiments including crystalline CdTe absorber materials, the disclosed methods include increasing the static dielectric constant of the absorber material to a value greater than 10.2.

With respect to methods of producing CdTe absorbers or devices, another Group II or Group VI element or elements may be incorporated into the absorber material to increase permittivity without causing significant detrimental changes to the basic material properties of the CdTe host material. For example, in embodiments featuring a crystalline CdTe absorber, the method embodiments may include additions guided by the potential for increasing the static dielectric constant of the resulting CdTe absorber alloy above 10.2. Therefore, Group 2/IIA elements may be incorporated into an absorber material, to replace some of the Cd. Suitable Group 2/IIA permittivity increasing materials include Be, Mg, Ca, Sr, and Ba. Similarly, Group 6/VIA elements may be incorporated to replace a portion of the Te, including Cr, Mo, and W.

Further, if the CdTe alloy is also to be doped, the dopant or a co-dopant may be selected to impart a higher dielectric constant to the resulting doped absorber material. For example, if p-type CdTe is required, as is the typical case for PV absorber materials, doping or co-doping with higher permittivity Group 1/IA materials (e.g., Li, Na, K, Rb) or Group 5/VA elements (e.g., V, Nb, Ta) can result in higher permittivity p-CdTe than would result from known doping (or co-doping) methods using typical Group 11/IB dopants (e.g., Cu, Ag, or Au) or Group 15/VB dopants (i.e., P, As, Sb, or Bi).

The permittivity increasing material may be incorporated into the absorber material according to any appropriate technique including but not limited to diffusion from other layers, co-deposition and/or deposition in layers followed by subsequent diffusion or activation steps.

Alternative embodiments include thin film photovoltaic absorbers having intentionally increased permittivity and devices having absorber layers with intentionally increased permittivity. Device and absorber embodiments may include absorber materials with increased permittivity created by the above methods. One representative but non-limiting device or absorber embodiment is a thin film photovoltaic absorber having increased permittivity comprising a crystalline CdTe alloy that includes a permittivity increasing material incorporated into the crystalline CdTe absorber material such that the CdTe alloy has a static dielectric constant greater than 10.2 and the permittivity increasing material comprises 0.01% to 10% of the absorber after incorporation.

In addition to the exemplary aspects and embodiments described above, further aspects and embodiments will become apparent by reference to the drawings and by study of the following descriptions

### BRIEF DESCRIPTION OF THE DETAILED DRAWINGS

Exemplary embodiments are illustrated in referenced figures of the drawings. It is intended that the embodiments and figures disclosed herein are to be considered illustrative rather than limiting.

FIG. 1A is a schematic diagram of an optimized prior-art CdS/CdTe PV device having most photons absorbed within the region of W_{D}

FIG. 1B is a schematic diagram of non-optimized prior-art CdS/CdTe PV device where W_{D} has become too small as the result of an increase of N_{A}.

FIG. 2 is a flowchart diagram illustrating one embodiment of device or absorber fabrication method as disclosed herein.

FIG. 3 is a schematic diagram of an optimized CdS/CdTe PV device featuring a high permittivity absorber.

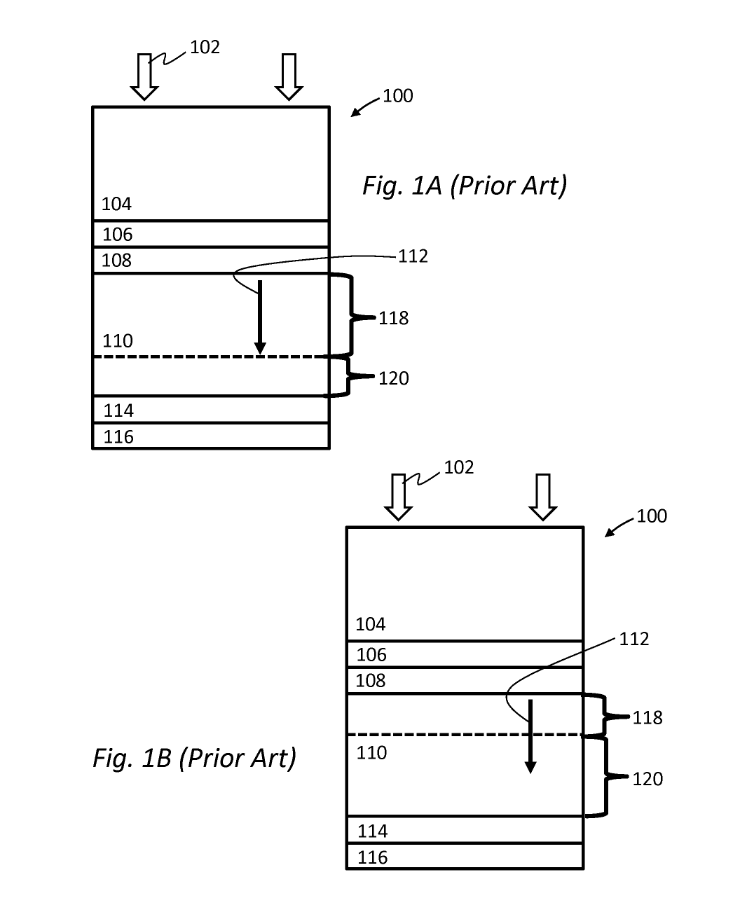

### DESCRIPTION

Unless otherwise indicated, all numbers expressing quantities of ingredients, dimensions, reaction conditions and so forth used in the specification and claims are to be understood as being modified in all instances by the term “about”.

In this application and the claims, the use of the singular includes the plural unless specifically stated otherwise. In addition, use of “or” means “and/or” unless stated otherwise. Moreover, the use of the term “including”, as well as other forms, such as “includes” and “included”, is not limiting. Also, terms such as “component” encompass both components comprising one unit and components that comprise more than one unit unless specifically stated otherwise.

Certain embodiments disclosed herein are methods useful for the manufacture of high efficiency photovoltaic (PV) devices, including but not limited to methods of manufacturing CdS/CdTe PV devices having a CdTe absorber. Other embodiments include specific CdS/CdTe PV devices and absorbers. The disclosed embodiments relate generally to fabrication methods and devices featuring absorber materials having lower than desired minority carrier lifetimes (τ). Therefore, although the embodiments are illustrated using CdS/CdTe PV technologies, the embodiments disclosed herein are not so limited and include similar methods, devices and absorber materials in the fields of CIGS, Cu₂ZnSn(S, Se)₄ (CZTS) compounds and other PV technologies or devices that can be improved by increasing the permittivity of the absorber material.

As noted above, it is generally desirable to increase both V_{oc} and device fill factor in a PV device, particularly if the absorber of the device has a relatively low τ. Low τ as used herein, indicates a τ value that substantially prevents minority carriers generated in a quasi-neutral region of an absorber from being collected. The embodiments disclosed herein include methods of increasing V_{oc} while reducing (or at least not increasing) voltage-dependant collection. As observed by the Applicants, Equation 2 above shows that W_{D} is not only a function of N_{A}, but also a function of ∈ₛ which is the static dielectric constant of the semiconductor material from which an absorber is fabricated. ∈ₛ is also known as the dielectric permittivity. Historically, ∈ₛ has been viewed as a material constant, and therefore not a controllable parameter.

With dielectric materials such as SiO₂ however, ∈ₛ can be varied significantly by the addition of relatively small amounts of refractory metal oxides, such as those related to Zr and Hf to a SiO₂ material. Further, permittivity variations also can be engineered into transparent conductive oxide materials (TCOs) such as In₂O₃:Sn, ZnO:Al, and SnO₂:F

From this, the Applicants appreciated that similar performance advantages can be realized for certain PV absorbers where the ∈ₛ of the absorber material is increased by incorporating a carefully selected permittivity increasing material in an alloy with the absorber material. For example, as Equation 2 indicates, when ∈ₛ increases, W_{D} will be larger for any given N_{A}. Accordingly, if a selected permittivity increasing material can increase ∈ₛ, the permittivity increasing material may also increase V_{oc} by increasing N_{A} without reducing W_{D}. In a higher ∈ₛ device, because W_{D} remains wider for any N_{A}.N_{D} product, more of the light will be absorbed within the space charge region W_{D} and less in the quasi-neutral region of the absorber, thereby reducing the detrimental effects of voltage-dependent collection described above. Therefore, depending on the extent that ∈ₛ can be increased without negatively impacting other electrical parameters, the disclosed devices and methods will produce devices with both higher V_{oc} and fill factor. As noted above, the disclosed methods, materials and devices are described below with respect to a CdTe absorber material. However, substitutions with and application to other materials having lower than desired static permittivity, including but not limited to CIGS and Cu₂ZnSn(S, Se)₄ (CZTS) compounds, are expressly asserted as being within the scope of embodiments provided by this disclosure.

For one representative but non-limiting absorber material; crystalline CdTe, the native dielectric constant is often quoted to be approximately 10.2. Because CdTe is a compound composed of a Group 12/IIB and a Group 16/VIB element, Cd and Te respectively, a relatively small amount of another Group II or Group VI element (or elements) may be incorporated into the absorber material without incurring significant changes in the basic material properties of the CdTe host material. The additional materials added to the absorber material are referred to collectively as permittivity increasing materials herein. The amount of permittivity increasing material added to an absorber layer may range from 0.01% to 10% or more specifically from 0.1% to 5%. Therefore, a permittivity increasing material is typically incorporated into an absorber material in a quantity significantly greater than conventional doping levels.

Suitable choice of permittivity increasing additions can be guided by the potential for increasing the static dielectric constant in any amount, from any starting point. For example, if the absorber material is crystalline CdTe, the resulting CdTe absorber, after permittivity increasing processes are employed as disclosed herein, may be an alloy having a dielectric constant above 10.2. Other absorber materials will have different starting dielectric constants which are increased in some amount. With respect to a CdTe absorber material, Group 2/IIA elements are of interest, to replace some Cd. Suitable Group 2/IIA permittivity increasing materials include Be, Mg, Ca, Sr, and Ba. Similarly, Group 6/VIA elements of interest, to replace a portion of the Te, include Cr, Mo, and W.

Further, if the CdTe alloy is also to be doped, the dopant or a co-dopant may be selected to impart a higher dielectric constant to the resulting doped absorber material. For example, if p-type CdTe is required, as is the typical case for present PV absorber materials, doping or co-doping with higher permittivity Group 1/IA materials (e.g., Li, Na, K, Rb) or Group 5/VA elements (e.g., V, Nb, Ta) may result in higher permittivity p-CdTe than would result from known doping (or co-doping) methods using Group 11/IB (e.g., Cu, Ag, or Au) or Group 15VB elements (i.e., P, As, Sb, or Bi).

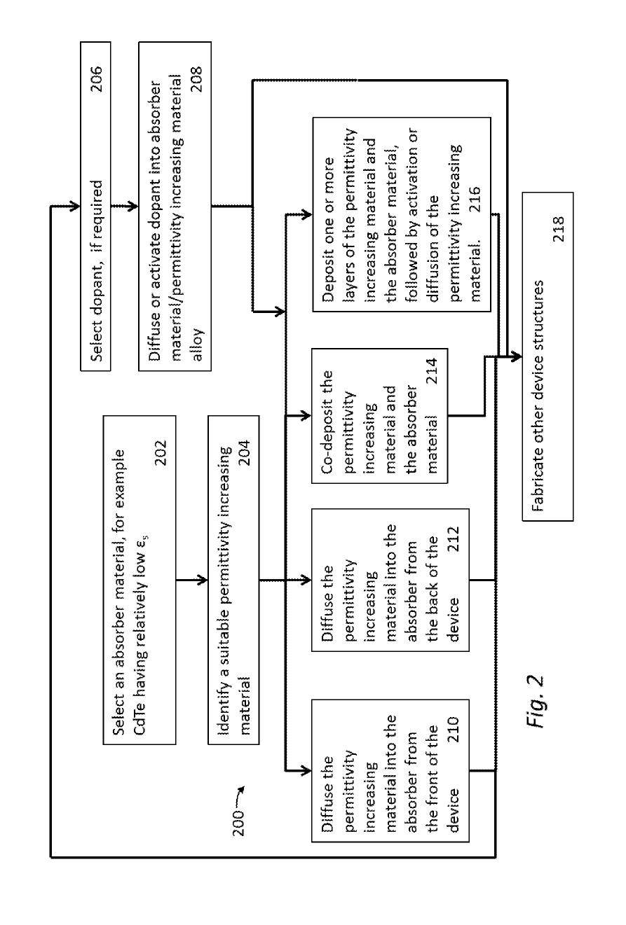

One method 200 of producing a thin film photovoltaic absorber or a thin film photovoltaic device in accordance with the foregoing discussion is detailed in the flowchart representation of FIG. 2. In particular, a PV absorber or device may be produced to have intentionally increased permittivity by incorporating a permittivity increasing material into the absorber material as a processing step. Initially, a suitable absorber material must be selected, for example the absorber material may be CdTe, CIGS, CZTS or another suitable material having lower than desired permittivity (Step 202). Then, a permittivity increasing material may be selected to alloy with absorber material. For example, if the absorber material is CdTe, a suitable permittivity increase material may be one or more of Be, Mg, Ca, Sr, and Ba to replace a portion of the Cd in the absorber or one or more of Cr, Mo and W to replace a portion of the Te in the absorber (Step 204). The permittivity increasing material should be a selected to avoid detrimentally changing the basic electrical and material properties of the absorber material while increasing the static dielectric constant ∈ₛ of the resulting alloy. For example, if the absorber material is CdTe, the resulting alloy (after incorporation of the permittivity increasing material) should impart a value of ∈ₛ greater than that of the native CdTe material.

Additionally, it may be necessary or desirable to dope or co-dope the CdTe alloy with a dopant. It is important to note that any desired doping step can occur at any suitable stage of a fabrication process, as indicated in FIG. 2, Steps 206-208. Furthermore, any selected dopant can be diffused or activated according to any method. The dopant may also be selected to increase the permittivity of the final absorber material in addition other reasons for doping (e.g. to impart n-type or p-type electrical characteristics to a material.) For example, in embodiments where the permittivity increasing material comprises one or more of Be, Mg, Ca, Sr, and Ba a suitable dopant may be one or more of Li, Na, K and Rb. Similarly, in embodiments where the permittivity increasing material comprises one or more of Cr, Mo and W a suitable dopant may be one or more of V, Nb and Ta.

The permittivity increasing material may be incorporated into the absorber material according to any suitable thin-film fabrication method. For example, in certain embodiments, the permittivity increasing material may be incorporated into the absorber by diffusion from a layer that is positioned towards the front of the device, including but not limited to a glass superstrate, TCO layer, buffer layer, CdS layer or the interface between one or more of these forward layers (Step 210). Alternatively, or in addition, the permittivity increasing material may be incorporated into the absorber material by diffusion from a rearward structure including but not limited to a metal contact layer, contact interface layer, the absorber layer or an interface between one or more of these layers (Step 212). Alternatively, the permittivity increasing material may be incorporated into the absorber by co-deposition with the absorber layer. Co-deposition of the absorber and permittivity increasing materials (or original deposition of the absorber material) may be performed according to any known and suitable deposition process (Step 214). Selected methods of incorporating a permittivity increasing material into an absorber material might include combinations of Steps 210-214, for example, as noted at Step 216, the permittivity increasing material may be incorporated by placing or depositing one or more layers of permittivity increasing material within the absorber layer, followed by diffusion or activation of the permittivity increasing material. A combination method is particularly well suited to situations where the absorber material and permittivity increasing material are best deposited using different deposition techniques.

In conjunction with the fabrication of an absorber having increased permittivity as described above, other steps may be taken and other processes performed, before, after or during the fabrication of the absorber, to create a device (Step 218).

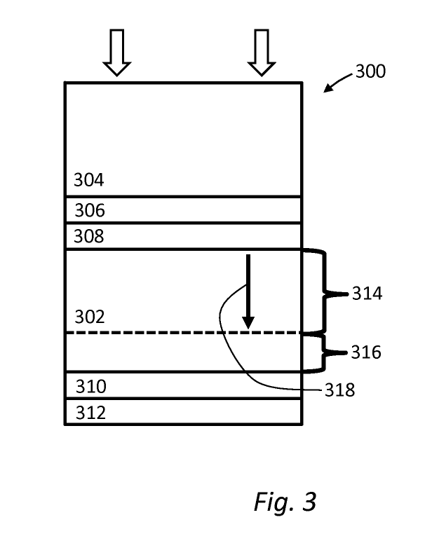

Alternative embodiments disclosed herein include PV absorber materials and PV devices fabricated or modified in accordance with the discussion above. As schematically illustrated in FIG. 3, one embodiment is a PV device 300 which includes an absorber 302 having intentionally increased permittivity. Although in one embodiment the device illustrated in FIG. 3 can be a CdS/CdTe PV device, the methods and materials disclosed herein are applicable to other types of devices, absorbers and materials including but not limited to CIGS, CZTS or other classes of device as explained above. The device 300 includes a superstrate 304 which is often, but not always a glass superstrate. The device 300 also includes one or more TCO and/or buffer layers 306 in physical contact with the superstrate 304. In one embodiment, device 300 includes an n-type CdS layer 308 in electrical contact with the p-type CdTe layer 302. A superstrate configured device such as device 300 also includes a back ohmic contact in electrical contact with the absorber 302. A typical back contact includes at least one contact interface layer 310 and an outer metallization layer 312 although fewer or more contact layers may be provided.

The device 300 may be distinguished from conventional CdS/CdTe PV devices because the absorber 302 includes a permittivity increasing material by design. The permittivity increasing material may comprise 0.01% to 10%, 0.1% to 5% or another suitable amount of the absorber after incorporation within the absorber. Other compositional balances of permittivity increasing material and absorber material are within the scope of the present disclosure and may be suitable for other materials. In embodiments where the absorber is primarily crystalline CdTe the permittivity increasing material may cause the resulting CdTe alloy to have a static dielectric constant of greater than 10.2. It is important to note however that the embodiments are not limited to this specific material or any specific level of increase in the static dielectric constant. Thus, as schematically represented in FIG. 3, the space charge width (W_{D}) 314 of the absorber 302 may be relatively large (when compared to an un-alloyed absorber) with respect to the quasi-neutral region 316 causing the absorption depth (represented by the arrow 318) to be within the space charge width 314.

The description of the disclosed embodiments has been presented for purposes of illustration and description, but is not intended to be exhaustive or limiting of the claims to any particular form disclosed. The scope of the present disclosure is limited only by the scope of the following claims. Many modifications and variations will be apparent to those of ordinary skill in the art. The embodiments described and shown in the figures were chosen and described in order to best explain the principles of the various embodiments, the practical application, and to enable others of ordinary skill in the art to understand the various embodiments with various modifications as are suited to the particular use contemplated.

While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope of the disclosure.

Various embodiments of the disclosure could also include permutations of the various elements recited in the claims as if each dependent claim was a multiple dependent claim incorporating the limitations of each of the preceding dependent claims as well as the independent claims. Such permutations are expressly within the scope of this disclosure.

What is claimed is:

1. A method of producing a thin film photovoltaic absorber having intentionally increased permittivity comprising incorporating a permittivity increasing material into a thin film photovoltaic absorber material.

2. The method of claim 1 wherein the permittivity increasing material comprises 0.01% to 10% of the thin film photovoltaic absorber after incorporation.

3. The method of claim 1 wherein the permittivity increasing material comprises 0.1% to 5% of the thin film photovoltaic absorber after incorporation.

4. The method of claim 1 wherein the thin film photovoltaic absorber, after incorporation of the permittivity increasing material, comprises a CdTe alloy and the CdTe alloy has a static dielectric constant greater than 10.2.

5. The method of claim 1 wherein the thin film photovoltaic absorber, after incorporation of the permittivity increasing material, comprises a CdTe alloy and the permittivity increasing material comprises one or more of Be, Mg, Ca, Sr, and Ba.

6. The method of claim 5 further comprising doping or co-doping the CdTe alloy with a dopant comprising one or more of Li, Na, K and Rb.

7. The method of claim 1 wherein the thin film photovoltaic absorber, after incorporation of the permittivity increasing material, comprises a CdTe alloy and the permittivity increasing material comprises one or more of Cr, Mo and W to replace a portion of the Te in the absorber.

8. The method of claim 7 further comprising doping or co-doping the CdTe alloy with a dopant comprising one or more of V, Nb and Ta.

9. The method of claim 1 wherein the permittivity increasing material is incorporated into the thin film photovoltaic absorber by diffusion from a device layer that is positioned toward the front of a device with respect to the thin film photovoltaic absorber.

10. The method of claim 9 wherein the device is a CdS/CdTe device and the permittivity increasing material is incorporated into the thin film photovoltaic absorber by diffusion from at least one of a glass superstrate, a transparent conducting oxide layer, a buffer layer, a CdS layer or the interface between one or more superstrate, transparent conducting oxide, buffer and CdS layers.

11. The method of claim 1 wherein the permittivity increasing material is incorporated into the thin film photovoltaic absorber by diffusion from a device layer that is positioned toward the back of a device with respect to the thin film photovoltaic absorber.

12. The method of claim 11 wherein the device is a CdS/CdTe device and the permittivity increasing material is incorporated into the thin film photovoltaic absorber by diffusion from at least one of a metal contact layer, a contact interface layer, the CdTe layer or the interface between one or more metal contact, contact interface and CdTe layers.

13. The method of claim 1 wherein the wherein the device is a CdS/CdTe device and the permittivity increasing material is incorporated into the thin film photovoltaic absorber by co-deposition with the thin film photovoltaic absorber.

14. A thin film photovoltaic absorber having increased permittivity comprising:
a thin film absorber material; and
a permittivity increasing material intentionally incorporated into the absorber material wherein the permittivity increasing material comprises 0.01% to 10% of the thin film photovoltaic absorber after incorporation.

15. The thin film photovoltaic absorber of claim 14 wherein the permittivity increasing material comprises 0.1% to 5% of the thin film photovoltaic absorber after incorporation therein.

16. The thin film photovoltaic absorber of claim 14 wherein the thin film photovoltaic absorber, after incorporation of the permittivity increasing material, comprises a CdTe alloy and the CdTe alloy has a static dielectric constant greater than 10.2.

17. The thin film photovoltaic absorber of claim 14 wherein the thin film photovoltaic absorber, after incorporation of the permittivity increasing material, comprises a CdTe alloy and the permittivity increasing material comprises one or more of Be, Mg, Ca, Sr, and Ba to replace a portion of the Cd in the absorber.

18. The thin film photovoltaic absorber of claim 17 further comprising a dopant comprising one or more of Li, Na, K and Rb.

19. The thin film photovoltaic absorber of claim 14 wherein the thin film photovoltaic absorber, after incorporation of the permittivity increasing material, comprises a CdTe alloy and the permittivity increasing material comprises one or more of Cr, Mo and W to replace a portion of the Te in the absorber.

20. The thin film photovoltaic absorber of claim 19 further comprising a dopant comprising one or more of V, Nb and Ta.

21. A thin film photovoltaic absorber having increased permittivity comprising a CdTe alloy that includes:
a thin film of CdTe absorber material; and
a permittivity increasing material incorporated into the CdTe absorber material;
wherein the CdTe alloy has a static dielectric constant greater than 10.2 and wherein the permittivity increasing material comprises 0.01% to 10% of the thin film photovoltaic absorber after incorporation.

22. A photovoltaic device comprising a thin film photovoltaic absorber having intentionally increased permittivity, wherein said photovoltaic absorber comprises a thin film absorber material and a permittivity increasing material incorporated into the absorber material, wherein the permittivity increasing material comprises 0.01% to 10% of the thin film photovoltaic absorber after incorporation.

23. The photovoltaic device of claim 22 wherein the thin film photovoltaic absorber, after incorporation of the permittivity increasing material, comprises a CdTe alloy and the device further comprises:
a glass superstrate;
a transparent conduction oxide operatively associated with the glass superstrate;
a CdS window layer operatively associated with the transparent conduction oxide and the CdTe absorber;
a contact interface layer operatively associated with the CdTe absorber; and
a metal back contact operatively associated with the contact interface layer.

24. The photovoltaic device of claim 22 wherein the permittivity increasing material comprises 0.1% to 5% of the thin film photovoltaic absorber after incorporation therein.

25. The photovoltaic device of claim 22 wherein the thin film photovoltaic absorber, after incorporation of the permittivity increasing material, comprises a CdTe alloy and the CdTe alloy has a static dielectric constant greater than 10.2.

26. The photovoltaic device of claim 22 wherein the thin film photovoltaic absorber, after incorporation of the permittivity increasing material, comprises a CdTe alloy and the permittivity increasing material comprises one or more of Be, Mg, Ca, Sr, and Ba.

27. The photovoltaic device of claim 24 further comprising a dopant comprising one or more of Li, Na, K and Rb.

28. The photovoltaic device of claim 22 wherein the thin film photovoltaic absorber, after incorporation of the permittivity increasing material, comprises a CdTe alloy and the permittivity increasing material comprises one or more of Cr, Mo and W.

29. The photovoltaic device of claim 27 further comprising a dopant comprising one or more of V, Nb and Ta.

30. The photovoltaic device 22 wherein the device is a CdS/CdTe device and the permittivity increasing material is incorporated into the thin film photovoltaic absorber by diffusion from at least one of the glass superstrate, the transparent conducting oxide layer, a buffer layer, the CdS window layer or an interface between one or more superstrate, transparent conducting oxide, buffer and CdS layers.

31. The photovoltaic device claim 22 wherein the device is a CdS/CdTe device and the permittivity increasing material is incorporated into the thin film photovoltaic absorber by diffusion from at least one of the metal contact layer, the contact interface layer, the CdTe absorber layer or the interface between one or more metal contact, contact interface and CdTe layers.

32. The photovoltaic device claim 22 wherein the permittivity increasing material is incorporated into the thin film photovoltaic absorber by co-deposition with the thin film photovoltaic absorber.

33. The photovoltaic device claim 22 wherein the permittivity increasing material is incorporated into the thin film photovoltaic absorber by co-deposition in layers with the thin film photovoltaic absorber and subsequent activation or diffusion of the permittivity increasing material.
